(19) United States
(12) Patent Application Publication
(10) Pub. No.: US 2011/0005810 A1
(43) Pub. Date: Jan. 13, 2011

(54) INSULATING SUBSTRATE AND METHOD FOR PRODUCING THE SAME

(75) Inventors: Daisuke Uneno, Oyama-shi (JP); Koji Hisayuki, Oyama-shi (JP)

Correspondence Address: EDWARDS ANGELL PALMER & DODGE LLP, P.O. BOX 55874, BOSTON, MA, 02205, US

(73) Assignee: Showa Denko K.K., Tokyo (JP)

(21) Appl. No.: 12/736,203

(22) PCT Filed: Mar. 19, 2009
(86) PCT No.: PCT/JP2009/055422

§ 371 Date: Sep. 20, 2010

(30) Foreign Application Priority Data
Mar. 25, 2008 (JP) 2008-077295

(51) Int. Cl. H05K 1/00; H05K 1/09; C04B 35/64

(52) U.S. Cl. 174/252; 174/250; 174/257; 174/258; 264/619

(57) ABSTRACT

An insulating substrate 1 includes an electrically insulative layer 2, a wiring layer 3 formed on one side of the electrically insulative layer 2 and formed of a spark plasma sintered body of an electrically conductive material powder, and a stress relaxation layer 4 formed on the other side of the electrically insulative layer 2 and formed of a spark plasma sintered body of an alloy powder or a mixed powder to be formed into a metal composite. The wiring layer 3 is formed of a spark sintered body of a powder selected from the group consisting of an Al powder, a Cu powder, an Ag powder, and an Au powder. The stress relaxation layer 4 is formed of a spark plasma sintered body of a powder selected from the group consisting of an Al—Si alloy powder, a mixed powder of a Cu powder and an Mo powder, a mixed powder of a Cu powder and a W powder, a mixed powder of an Al powder and an SiC powder, and a mixed powder of an Si powder and an SiC powder. Use of the insulating substrate can yield a power module which can prevent a drop in heat radiation performance and can enhance durability.

### TECHNICAL FIELD

The present invention relates to an insulating substrate for mounting thereon, for example, a semiconductor device, and to a method of manufacturing the same.

The term “aluminum” as used herein encompasses aluminum alloys in addition to pure aluminum, except for the case where “pure aluminum” is specified. Needless to say, metal as expressed by an elemental symbol indicates pure metal.

### BACKGROUND ART

In recent years, in order to control large power, a power module which includes a power device formed of a semiconductor device, such as an IGBT (Insulated Gate Bipolar Transistor), has been widely used. In such a power module, the semiconductor device must be held at a predetermined temperature or lower by means of efficiently radiating heat generated therefrom. A base for a power module (hereinafter referred to as a “power module base”) which meets the requirement has conventionally been proposed (see Patent Document 1). The power module base includes a ceramic insulating substrate having an electrically insulative layer formed of ceramic, such as aluminum oxide (Al₂O₃) or aluminum nitride (AlN), an aluminum wiring layer formed on one side of the electrically insulative layer, and an aluminum heat transfer layer formed on the other side of the electrically insulative layer; an aluminum heat radiation substrate soldered or brazed to the heat transfer layer of the insulating substrate; and an aluminum heat sink screwed to a side of the heat radiation substrate opposite the side brazed to the insulating substrate. A cooling liquid flow path is formed within the heat sink.

In the power module base described in Patent Document 1, a power device is mounted on the wiring layer of the insulating substrate, thereby completing a power module. Heat generated from the power device is transferred to the heat sink via the wiring layer, the electrically insulative layer, the heat transfer layer, and the heat radiation substrate and is radiated to a cooling liquid flowing through the cooling liquid flow path.

At this time, the heat radiation substrate and the heat sink, which are formed of aluminum having a relatively high thermal expansion coefficient, have a high temperature through subjection to heat generated from the power device and tend to thermally expand to a relatively large extent. Meanwhile, since ceramic used to form the electrically insulative layer of the insulating substrate is lower in thermal expansion coefficient than aluminum, even though the electrically insulative layer has a high temperature through subjection to heat generated from the power device, the electrically insulative layer does not thermally expand to such a large extent as do the heat radiation substrate and the heat sink. Therefore, if no measure is taken, due to the difference in thermal expansion between the insulating substrate and each of the heat radiation substrate and the heat sink, the heat radiation substrate and the heat sink are pulled by the insulating substrate and warped accordingly. As a result, generation of a crack in the insulating substrate, separation of joined surfaces, and an impairment in durability arise.

In the power module base described in Patent Document 1, the heat radiation substrate is configured such that a low-thermal-expansion material, such as Invar, intervenes between paired plate-like heat radiation bodies formed of a high-thermal-conduction material, such as aluminum or copper (including copper alloys; hereinafter, the same is applied).

However, in a power module in which a power device is mounted on the wiring layer of the power module base described in Patent Document 1, since the wiring layer, the electrically insulative layer, the heat transfer layer, and the heat radiation substrate are present between the power device and the heat sink, a heat conduction path from the power device to the heat sink becomes long, with a resultant drop in heat radiation performance. Also, since the heat radiation substrate and the heat sink are merely screwed together, thermal conductivity therebetween is insufficient, resulting in a failure to exhibit sufficient heat radiation performance.

Patent Document 1: Japanese Patent Application Laid-Open (kokai) No. 2004-153075

### DISCLOSURE OF THE INVENTION

### Problems to be Solved by the Invention

An object of the present invention is to solve the above problem and to provide an insulating substrate for use in a power module which can prevent a drop in heat radiation performance and can enhance durability.

### Means for Solving the Problems

To achieve the above object, the present invention comprises the following modes.

1) An insulating substrate comprising an electrically insulative layer; a wiring layer formed on one side of the electrically insulative layer and formed of a spark plasma sintered body of an electrically conductive material powder; and a stress relaxation layer formed on the other side of the electrically insulative layer and formed of a spark plasma sintered body of an alloy powder or a mixed powder to be formed into a metal composite.

2) An insulating substrate according to par. 1), wherein the electrically insulative layer is formed of a spark sintered body of a powder selected from the group consisting of an AlN powder, an Si₃N₄ powder, an Al₂O₃ powder, and a BeO powder.

3) An insulating substrate according to par. 1), wherein the wiring layer is formed of a spark sintered body of a powder selected from the group consisting of an Al powder, a Cu powder, an Ag powder, and an Au powder.

4) An insulating substrate according to par. 1), wherein the stress relaxation layer is formed of a spark plasma sintered body of a powder-selected from the group consisting of an Al—Si alloy powder, a mixed powder of a Cu powder and an Mo powder, a mixed powder of a Cu powder and a W powder, a mixed powder of an Al powder and an SiC powder, and a mixed powder of an Si powder and an SiC powder.

5) An insulating substrate according to par. 1), wherein a thermal expansion coefficient of the stress relaxation layer falls between a thermal expansion coefficient of the electrically insulative layer and a thermal expansion coefficient of the wiring layer.

6) An insulating substrate according to par. 1), wherein at least the stress relaxation layer selected from the wiring layer and the stress relaxation layer has a circular shape.

7) An insulating substrate according to par. 1), wherein at least the stress relaxation layer selected from the wiring layer and the stress relaxation layer has an elliptic shape.

Notably, the term “elliptic shape” as used herein and in the appended claims encompasses an elliptic shape in a strict sense as defined mathematically and an elongated circular shape close to a mathematically defined elliptic shape.

8) An insulating substrate according to par. 1), wherein at least the stress relaxation layer selected from the wiring layer and the stress relaxation layer has a polygonal shape having radiused corners.

9) A power module base comprising an insulating substrate according to any one of pars. 1) to 8) and a heat sink, to which the stress relaxation layer of the insulating substrate is welded or brazed.

10) A power module base comprising an insulating substrate according to any one of pars. 1) to 8) and a heat sink, to which the stress relaxation layer of the insulating substrate is bonded by means of a highly heat conductive adhesive.

11) A method of manufacturing an insulating substrate comprising forming a wiring layer on one side of an electrically insulative layer in the form of an insulating plate through spark plasma sintering of an electrically conductive material powder, and forming a stress relaxation layer on the other side of the electrically insulative layer through spark plasma sintering of an alloy powder or a mixed powder to be formed into a metal composite.

12) A method of manufacturing an insulating substrate according to par. 11), wherein the electrically insulative layer in the form of an insulating plate is formed through spark plasma sintering of a powder selected from the group consisting of an AlN powder, an Si₃N₄ powder, an Al₂O₃ powder, and a BeO powder.

13) A method of manufacturing an insulating substrate according to par. 11), wherein the electrically conductive material powder used to form the wiring layer is a powder selected from the group consisting of an Al powder, a Cu powder, an Ag powder, and an Au powder.

14) A method of manufacturing an insulating substrate according to par. 11), wherein the alloy powder which is used to form the stress relaxation layer is an Al—Si alloy, and the mixed powder to be formed into a metal composite which is used to form the stress relaxation layer is a mixed powder selected from the group consisting of a mixed powder of a Cu powder and an Mo powder, a mixed powder of a Cu powder and a W powder, a mixed powder of an Al powder and an SiC powder, and a mixed powder of an Si powder and an SiC powder.

### EFFECTS OF THE INVENTION

The insulating substrate of par. 1) is used as follows: the stress relaxation layer of the insulating substrate is joined to a heat sink formed of a high-thermal-conduction material, such as aluminum or copper, through welding or brazing, or bonding by use of a highly heat conductive adhesive, and a power device is mounted on the wiring layer of the power module base, thereby completing a power module. Since only the wiring layer, the electrically insulative layer, and the stress relaxation layer are present between the power device and the heat sink, as compared with a power module which uses the insulating substrate described in Patent Document 1, a heat conduction path from the power device to the heat sink becomes shorter, thereby enhancing radiation performance for heat generated from the power device. Also, since the wiring layer and the stress relaxation layer are spark plasma sintered bodies formed respectively on the electrically insulative layer, there is no need to dispose a brazing material having a low thermal expansion coefficient between the electrically insulative layer and each of the wiring layer and the stress relaxation layer, whereby excellent thermal conductivity is established between the electrically insulative layer and each of the wiring layer and the stress relaxation layer.

Further, even when thermal stress is generated in the power module base from a phenomenon in which the difference in thermal expansion coefficient between the heat sink and the electrically insulative layer of the insulating substrate causes the heat sink to be pulled by the electrically insulative layer and thus to attempt to warp, the stress relaxation layer functions to relax thermal stress, thereby preventing generation of a crack in the electrically insulative layer and generation of warpage of a joint surface of the heat sink joined to the stress relaxation layer. Therefore, radiation performance is maintained for a long period of time.

According to the insulating substrate of par. 3), excellent electrical conductivity and excellent thermal conductivity are imparted to the wiring layer.

According to the insulating substrate of par. 4), excellent thermal conductivity is imparted to the stress relaxation layer. Further, in the case of use of a power module in which a power device is mounted on a power module base which uses the insulating substrate, when thermal stress is generated in the power module base, the stress relaxation layer yields an excellent thermal-stress relaxation effect.

According to the insulating substrate of par. 5), the following advantageous effect is attained. In the case of use of a power module in which a power device is mounted on a power module base which uses the insulating substrate, when thermal stress is generated in the power module base, the stress relaxation layer yields an excellent thermal-stress relaxation effect.

In the case of the insulating substrate of any one of pars. 6) to 8), even when thermal stress is generated in the power module base of the above-described power module from a phenomenon in which the difference in thermal expansion coefficient between the heat sink and the electrically insulative layer of the insulating substrate causes the heat sink to be pulled by the electrically insulative layer and thus to attempt to warp, since the external shape of the stress relaxation layer does not have an edge portion where thermal stress is concentrated, separation of the stress relaxation layer and the heat sink can be prevented more reliably.

According to the power module base of par. 9) or 10), since only the wiring layer, the electrically insulative layer, and the stress relaxation layer are present between a power device and a heat sink in a power module in which the power device is mounted on the wiring layer, as compared with a power module which uses the power module base described in Patent Document 1, a heat conduction path from the power device to the heat sink becomes shorter, thereby enhancing radiation performance for heat generated from the power device. Also, since the wiring layer and the stress relaxation layer are formed of respective spark plasma sintered bodies, excellent thermal conductivity is imparted to the wiring layer and the stress relaxation layer.

Further, even when thermal stress is generated in the power module base from a phenomenon in which the difference in thermal expansion coefficient between the heat sink and the electrically insulative layer of the insulating substrate causes the heat sink to be pulled by the electrically insulative layer and thus to attempt to warp, the stress relaxation layer functions to relax thermal stress, thereby preventing generation of a crack in the electrically insulative layer and generation of warpage of a joint surface of the heat sink joined to the stress relaxation layer. Therefore, radiation performance is maintained for a long period of time.

According to the method of manufacturing an insulating substrate of par. 11), the insulating substrate of par. 1) can be manufactured easily.

According to the method of manufacturing an insulating substrate of par. 13), excellent electrical conductivity and excellent thermal conductivity are imparted to the wiring layer of a manufactured insulating substrate.

According to the method of manufacturing an insulating substrate of par. 14), excellent thermal conductivity is imparted to the stress relaxation layer of a manufactured insulating substrate. Further, in the case of use of a power module in which a power device is mounted on a power module base which uses the manufactured insulating substrate, when thermal stress is generated in the power module base, the stress relaxation layer yields an excellent thermal-stress relaxation effect.

According to the manufacturing method of any one of pars. 11) to 14), the insulating substrate of any one of pars. 6) to 8) can be manufactured without involvement of waste of material. That is, in the case where at least the stress relaxation layer selected from the wiring layer and the stress relaxation layer is manufactured from a material plate through cutting, material pieces to be disposed of increase, resulting in an increase in cost.

### BEST MODE FOR CARRYING OUT THE INVENTION

Embodiments of the present invention will next be described with reference to the drawings. In the following description, the upper and lower sides of FIGS. 1 and 3 will be referred to as “upper” and “lower,” respectively.

FIGS. 1 and 2 show an insulating substrate according to the present invention. FIG. 3 shows a power module configured such that a power device is mounted on a power module base which uses the insulating substrate of FIGS. 1 and 2.

In FIGS. 1 and 2, the insulating substrate (1) includes an electrically insulative layer (2); a wiring layer (3) formed on one side (upper surface) of the electrically insulative layer (2) and formed of a spark plasma sintered body of an electrically conductive material; and a stress relaxation layer (4) formed on the other side (lower surface) of the electrically insulative layer (2) and formed of a spark plasma sintered body of an alloy powder or a mixed powder to be formed into a metal composite.

The electrically insulative layer (2), the wiring layer (3), and the stress relaxation layer (4) each have a square shape having right-angled corners as viewed in plane.

The electrically insulative layer (2) is formed of a spark plasma sintered body of a powder selected from the group consisting of an AlN powder, an Si₃N₄ powder, an Al₂O₃ powder, and a BeO powder. The electrically insulative layer (2) may be formed through hot isostatic pressing (HIP) by use of a powder selected from the group consisting of an AlN powder, an Si₃N₄ powder, an Al₂O₃ powder, and a BeO powder. The ceramics have the following thermal expansion coefficients (typical values): AlN: 4.3 ppm/K; Si₃N₄: 2.7 ppm/K; Al₂O₃: 7.4 ppm/K; and BeO: 7.5 ppm/K.

The wiring layer (3) is formed of a spark plasma sintered body of a powder selected from the group consisting of an Al powder, a Cu powder, an Ag powder, and an Au powder. The metals have the following thermal expansion coefficients (typical values): Al: 23.5 ppm/K; Cu: 17.0 ppm/K; Ag: 19.1 ppm/K; and Au: 14.1 ppm/K. Although unillustrated, the wiring layer (3) has circuits formed thereon. The circuits are formed through etching performed after formation of the wiring layer (3) through spark plasma sintering, or formed in the course of formation of the wiring layer (3) through spark plasma sintering.

The stress relaxation layer (4) is formed of a spark plasma sintered body of a powder selected from the group consisting of an Al—Si alloy powder, a mixed powder of a Cu powder and an Mo powder, a mixed powder of a Cu powder and a W powder, a mixed powder of an Al powder and an SiC powder, and a mixed powder of an Si powder and an SiC powder. Notably, the spark plasma sintered bodies of the above-mentioned mixed powders are metal composites. The alloy and the metal composites have the following thermal expansion coefficients (typical values): Al—Si alloy: 15 ppm/K to 22 ppm/K; Cu—Mo composite: 7 ppm/K to 10 ppm/K; Cu—W composite: 6.5 ppm/K to 8.5 ppm/K; Al—SiC composite: 7 ppm/K to 17 ppm/K; and Si—SiC composite: 3 ppm/K.

It is good practice to select materials for forming the electrically insulative layer (2), the wiring layer (3), and the stress relaxation layer (4) in such a manner that a thermal expansion coefficient of the stress relaxation layer (4) falls between a thermal expansion coefficient of the electrically insulative layer (2) and a thermal expansion coefficient of the wiring layer (3).

As shown in FIG. 3, a power module (P) includes a power module base (6) composed of the insulating substrate (1) and a heat sink (5), to which the stress relaxation layer (4) of the insulating substrate (1) is joined, and a power device (7) mounted through soldering on the wiring layer (3) of the insulating substrate (1) of the power module base (6).

Preferably, the heat sink (5) has a plurality of flat hollow cooling fluid channels (8) juxtaposed to one another and is formed of aluminum, which has excellent thermal conductivity and is light. Cooling fluid may be liquid or gas. The stress relaxation layer (4) of the insulating substrate (1) is welded or brazed to the external surface of an upper wall (5a) of the heat sink (5). The stress relaxation layer (4) of the insulating substrate (1) may be bonded to the external surface of the upper wall (5a) of the heat sink (5) by use of a highly heat conductive adhesive.

In place of a heat sink having a plurality of flat hollow cooling fluid channels juxtaposed to one another, a heat sink having heat radiation fins provided on one side of a heat radiation substrate may be used. In this case, the stress relaxation layer (4) of the insulating substrate (1) is joined, in a manner similar to that mentioned above, to a side of the heat radiation substrate on which the heat radiation fins are not provided.

In the above-mentioned power module (P), heat generated from the power device (7) is transferred to the upper wall (5a) of the heat sink (5) via the wiring layer (3), the electrically insulative layer (2), and the stress relaxation layer (4) and is radiated from the upper wall (5a) to cooling fluid flowing through the cooling fluid channels (8). In this case, even when thermal stress is generated in the power module base (6) from a phenomenon in which the difference in thermal expansion coefficient between the heat sink (5) and the electrically insulative layer (2) of the insulating substrate (1) causes the heat sink (5) to be pulled by the electrically insulative layer (2) and thus to attempt to warp, the stress relaxation layer (4) functions to relax thermal stress, thereby preventing generation of a crack in the electrically insulative layer (2) and generation of warpage of a joint surface of the heat sink (5) joined to the stress relaxation layer (4).

Next, a method of manufacturing the insulating substrate (1) will be described.

A powder selected from the group consisting of an AlN powder, an Si₃N₄ powder, an Al₂O₃ powder, and a BeO powder which are produced by an ordinary production method is used. These powders may be formed into finer powders through mechanical alloying by use of a planetary ball mill, an attritor mill, or a pot mill. Mechanical alloying takes one hour to 15 hours. A powder which is not subjected to mechanical alloying and a powder which is rendered finer through mechanical alloying have an average particle size ranging from several micrometers to several hundreds of micrometers. The powder is subjected to spark plasma sintering, thereby forming the electrically insulative layer (2) formed of a spark plasma sintered body of a powder selected from the group consisting of an AlN powder, an Si₃N₄ powder, an Al₂O₃ powder, and a BeO powder. Alternatively, the above-mentioned powder is subjected to hot isostatic pressing, thereby forming the electrically insulative layer (2) formed of a powder selected from the group consisting of an AlN powder, an Si₃N₄ powder, an Al₂O₃ powder, and a BeO powder.

Spark plasma sintering conditions for a powder selected from the group consisting of an AlN powder, an Si₃N₄ powder, an Al₂O₃ powder, and a BeO powder depend on the size of the electrically insulative layer (2) to be formed. For example, the above-mentioned powder is heated through resistance heating at a sintering temperature of 1,500° C. to 2,200° C. under the following conditions: applied pulse current: 1,000 A to 10,000 A; applied pressure: 10 MPa to 100 MPa; and sintering-temperature retention time: 5 min to 40 min.

Also, a powder selected from the group consisting of an Al powder, a Cu powder, an Ag powder, and an Au powder which are produced by an ordinary production method is used. These powders may be formed into finer powders through mechanical alloying by use of a planetary ball mill, an attritor mill, or a pot mill. Mechanical alloying takes one hour to 15 hours. A powder which is not subjected to mechanical alloying and a powder which is rendered finer through mechanical alloying have an average particle size ranging from several micrometers to several hundreds of micrometers.

Also, an Al—Si alloy powder, a Cu powder, an Mo powder, a W powder, an Al powder, an Si powder, an SiC powder, and an SiC powder which are produced by an ordinary production method are used. These powders may be formed into finer powders through mechanical alloying by use of a planetary ball mill, an attritor mill, or a pot mill. Mechanical alloying takes one hour to 15 hours. A powder which is not subjected to mechanical alloying and a powder which is rendered finer through mechanical alloying have an average particle size ranging from several micrometers to several hundreds of micrometers. The Al—Si alloy powder used to form the stress relaxation layer (4) formed of Al—Si alloy is formed from an alloy which contains Si in an amount of 11% by mass to 20% by mass and the balance consisting of Al and unavoidable impurities. In the case of forming the stress relaxation layer (4) formed of Cu—Mo composite, a Cu powder and an Mo powder are mixed at a mixing ratio by volume of Cu:Mo=60:40 to 15:85, thereby yielding a mixed powder. In the case of forming the stress relaxation layer (4) formed of Cu—W composite, a Cu powder and a W powder are mixed at a mixing ratio by volume of Cu:W=20:80 to 10:90, thereby yielding a mixed powder. In the case of forming the stress relaxation layer (4) formed of Al—SiC composite, an Al powder and an SiC powder are mixed at a mixing ratio by volume of Al:SiC=80:20 to 20:80, thereby yielding a mixed powder. In the case of forming the stress relaxation layer (4) formed of Si—SiC composite, an Si powder and an SiC powder are mixed at a mixing ratio by volume of Si:SiC=15:85 to 20:80, thereby yielding a mixed powder.

Subsequently, the above-yielded powder selected from the group consisting of an Al powder, a Cu powder, an Ag powder, and an Au powder is spark-plasma-sintered on-one side of the previously formed electrically insulative layer (2), thereby forming the wiring layer (3) formed of a spark plasma sintered body of the powder. At the same time, the above-yielded alloy powder or mixed powder is spark-plasma-sintered on the other side of the electrically insulative layer (2), thereby forming the stress relaxation layer (4) formed of a spark plasma sintered body of a powder selected from the group consisting of an Al—Si alloy powder, a mixed powder of a Cu powder and an Mo powder, a mixed powder of a Cu powder and a W powder, a mixed powder of an Al powder and an SiC powder, and a mixed powder of an Si powder and an SiC powder. The insulating substrate (1) is thus manufactured.

Spark plasma sintering conditions for a powder selected from the group consisting of an Al powder, a Cu powder, an Ag powder, and an Au powder and spark plasma sintering conditions for a powder selected from the group consisting of an Al—Si alloy powder, a mixed powder of a Cu powder and an Mo powder, a mixed powder of a Cu powder and a W powder, a mixed powder of an Al powder and an SiC powder, and a mixed powder of an Si powder and an SiC powder depend on the sizes of the wiring layer (3) and the stress relaxation layer (4) to be formed. For example, the above-mentioned powders are heated through resistance heating at a sintering temperature of 400° C. to 1,400° C. under the following conditions: applied pulse current: 400 A to 2,000 A; applied pressure: 10 MPa to 100 MPa; and sintering-temperature retention time: 1 min to 40 min.

Specific examples of the insulating substrate (1) according to the present invention will next be described together with comparative examples.

### Example 1

An AlN powder having an average particle size of 6 μm and produced by an ordinary production method was placed in a die of graphite. A pair of electrodes was disposed in such a manner as to face the interior of the die. Subsequently, in a state in which a uniaxial pressure of 50 MPa was imposed on the AlN powder, spark plasma sintering was performed through application of a pulse current of 2,000 A maximum between the paired electrodes and through retention at a sintering temperature for five minutes, thereby forming the electrically insulative layer (2) having a square shape with 50 mm on sides and a thickness of 0.635 mm. In the above-mentioned spark plasma sintering, sintering temperature for the AlN powder was 1,800° C.

An Al powder having an average particle size of 100 μm was produced through gas atomizing. The gas-atomized Al powder having an average particle size of 100 μm and an SiC powder having an average particle size of 10 μm produced by an ordinary production method were mixed at a mixing ratio by volume of Al:SiC=50:50, thereby yielding a mixed powder.

Next, dies of graphite were disposed on respective opposite sides of the electrically insulative layer (2). The Al powder was placed in the die disposed on one side of the electrically insulative layer (2), and the mixed powder of the Al powder and the SiC powder was placed in the die disposed on the other side of the electrically insulative layer (2). A pair of electrodes was disposed in such a manner as to face the interiors of the dies. Subsequently, in a state in which a uniaxial pressure of 20 MPa was imposed on the Al powder, spark plasma sintering was performed through application of a pulse current of 1,500 A maximum between the paired electrodes and through retention at a sintering temperature for three minutes, thereby forming the wiring layer (3) having a square shape with 48 mm on sides and a thickness of 0.6 mm and joined to one side of the electrically insulative layer (2). At the same time, in a state in which a uniaxial pressure of 20 MPa was imposed on the mixed powder of the Al powder and the SiC powder, spark plasma sintering was performed through application of a pulse current of 1,500 A maximum between the paired electrodes and through retention at a sintering temperature for three minutes, thereby forming the stress relaxation layer (4) having a square shape with 50 mm on sides and a thickness of 0.6 mm and joined to the other side of the electrically insulative layer (2). In the above-mentioned spark plasma sintering, sintering temperature for the Al powder and the mixed powder of the Al powder and the SiC powder was 550° C.

The insulating substrate (1) was thus manufactured.

### Example 2

An AlN powder having an average particle size of 6 μm and produced by an ordinary production method was placed in a die of graphite. A pair of electrodes was disposed in such a manner as to face the interior of the die. Subsequently, in a state in which a uniaxial pressure of 50 MPa was imposed on the AlN powder, spark plasma sintering was performed through application of a pulse current of 1,000 A maximum between the paired electrodes and through retention at a sintering temperature for five minutes, thereby forming the electrically insulative layer (2) having a square shape with 12 mm on sides and a thickness of 0.635 mm. In the above-mentioned spark plasma sintering, sintering temperature for the AlN powder was 1,800° C.

An Al powder having an average particle size of 100 μm was produced through gas atomizing. The gas-atomized Al powder having an average particle size of 100 μm and an SiC powder having an average particle size of 10 μm produced by an ordinary production method were mixed at a mixing ratio by volume of Al:SiC=50:50, thereby yielding a mixed powder.

Next, dies of graphite were disposed on respective opposite sides of the electrically insulative layer (2). The Al powder was placed in the die disposed on one side of the electrically insulative layer (2), and the mixed powder of the Al powder and the SiC powder was placed in the die disposed on the other side of the electrically insulative layer (2). A pair of electrodes was disposed in such a manner as to face the interiors of the dies. Subsequently, in a state in which a uniaxial pressure of 20 MPa was imposed on the Al powder, spark plasma sintering was performed through application of a pulse current of 500 A maximum between the paired electrodes and through retention at a sintering temperature for three minutes, thereby forming the wiring layer (3) having a square shape with 10 mm on sides and a thickness of 0.6 mm and joined to one side of the electrically insulative layer (2). At the same time, in a state in which a uniaxial pressure of 20 MPa was imposed on the mixed powder of the Al powder and the SiC powder, spark plasma sintering was performed through application of a pulse current of 500 A maximum between the paired electrodes and through retention at a sintering temperature for three minutes, thereby forming the stress relaxation layer (4) having a square shape with 12 mm on sides and a thickness of 0.6 mm and joined to the other side of the electrically insulative layer (2). In the above-mentioned spark plasma sintering, sintering temperature for the Al powder and the mixed powder of the Al powder and the SiC powder was 550° C.

The insulating substrate (1) was thus manufactured.

### Comparative Example 1

An AlN plate having a square shape with 50 mm on sides and a thickness of 0.635 mm and Al plates each having a square shape with 48 mm on sides and a thickness of 0.6 mm were prepared. By use of a brazing material of an Al—Si alloy, the Al plates were brazed to respective opposite sides of the AlN plate, thereby manufacturing an insulating substrate. The thickness of the brazing material between the AlN plate and each of the two Al plates was 0.05 mm. In the thus-manufactured insulating substrate, one Al plate serves as a wiring layer, and the other Al plate serves as a stress relaxation layer.

### Comparative Example 2

An AlN plate having a square shape with 12 mm on sides and a thickness of 0.635 mm and Al plates each having a square shape with 10 mm on sides and a thickness of 0.6 mm were prepared. By use of a brazing material of an Al—Si alloy, the Al plates were brazed to respective opposite sides of the AlN plate, thereby manufacturing an insulating substrate. The thickness of the brazing material between the AlN plate and each of the two Al plates was 0.05 mm. In the thus-manufactured insulating substrate, one Al plate serves as a wiring layer, and the other Al plate serves as a stress relaxation layer.

Evaluation test:

By use of the insulating substrates of Examples 1 and 2 and Comparative Examples 1 and 2, thermal resistance was measured between the surface (upper surface in FIG. 1) of the wiring layer and the surface of the stress relaxation layer. The measured thermal resistances were as follows: insulating substrate of Example 1: 0.0041 K/W; insulating substrate of Example 2: 0.0791 K/W; insulating substrate of Comparative Example 1: 0.0044 K/W; and insulating substrate of Comparative Example 2: 0.0928 K/W.

As is apparent from the results, in the case of the same dimensions, the insulating substrates of the present invention are superior in thermal conductivity in the thickness direction to the insulating substrates of Comparative Examples 1 and 2.

FIGS. 4 to 6 show modified stress relaxation layers of the insulating substrate.

A stress relaxation layer (10) shown in FIG. 4 has a circular shape as viewed in plane.

A stress relaxation layer (11) shown in FIG. 5 has an elliptic shape as viewed in plane.

A stress relaxation layer (12) shown in FIG. 6 has a polygonal shape, herein a rectangular shape, having radiused corners as viewed in plane.

In the case of the stress relaxation layers (10), (11), and (12) shown in FIGS. 4 to 6, the electrically insulative layer (2) to be used has the same shape and the same size as those of the stress relaxation layers (10), (11), and (12); the same shape as those of and a size greater than those of the stress relaxation layers (10), (11), and (12); or a shape different from those of and a size greater than those of the stress relaxation layers (10), (11), and (12).

Similar to the stress relaxation layers shown in FIGS. 4 to 6, the wiring layer of the insulating substrate may have a circular shape, an elliptic shape, or a polygonal shape having rounded corners. In this case also, the electrically insulative layer (2) to be used has the same shape as that of and the same size as that of the wiring layer; the same shape as that of and a size greater than that of the wiring layer; or a shape different from that of and a size greater than that of the wiring layer.

### INDUSTRIAL APPLICABILITY

The insulating substrate of the present invention is preferably used in a power module adapted to cool a semiconductor device serving as a power device.

### BRIEF DESCRIPTION OF THE DRAWINGS

FIG. 1 is a vertical section showing an insulating substrate according to the present invention.

FIG. 2 is a plan view showing the insulating substrate according to the present invention.

FIG. 3 is a vertical section showing a power module configured such that a power device is mounted on a power module base which uses the insulation substrate of FIG. 1.

FIG. 4 is a plan view showing a first modified stress relaxation layer.

FIG. 5 is a plan view showing a second modified stress relaxation layer.

FIG. 6 is a plan view showing a third modified stress relaxation layer.

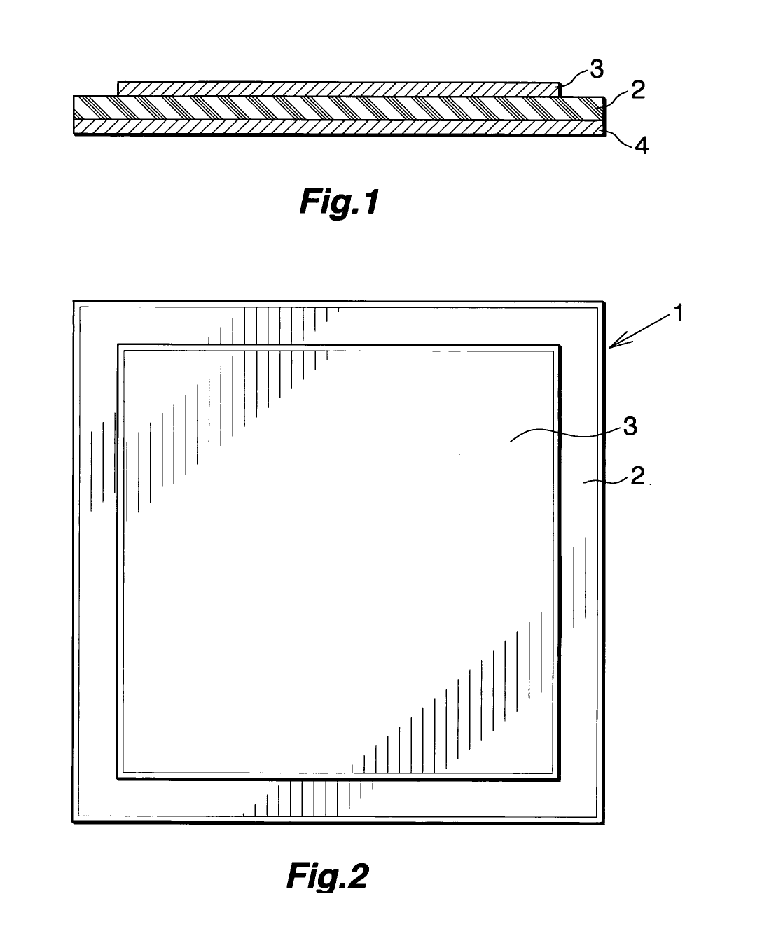

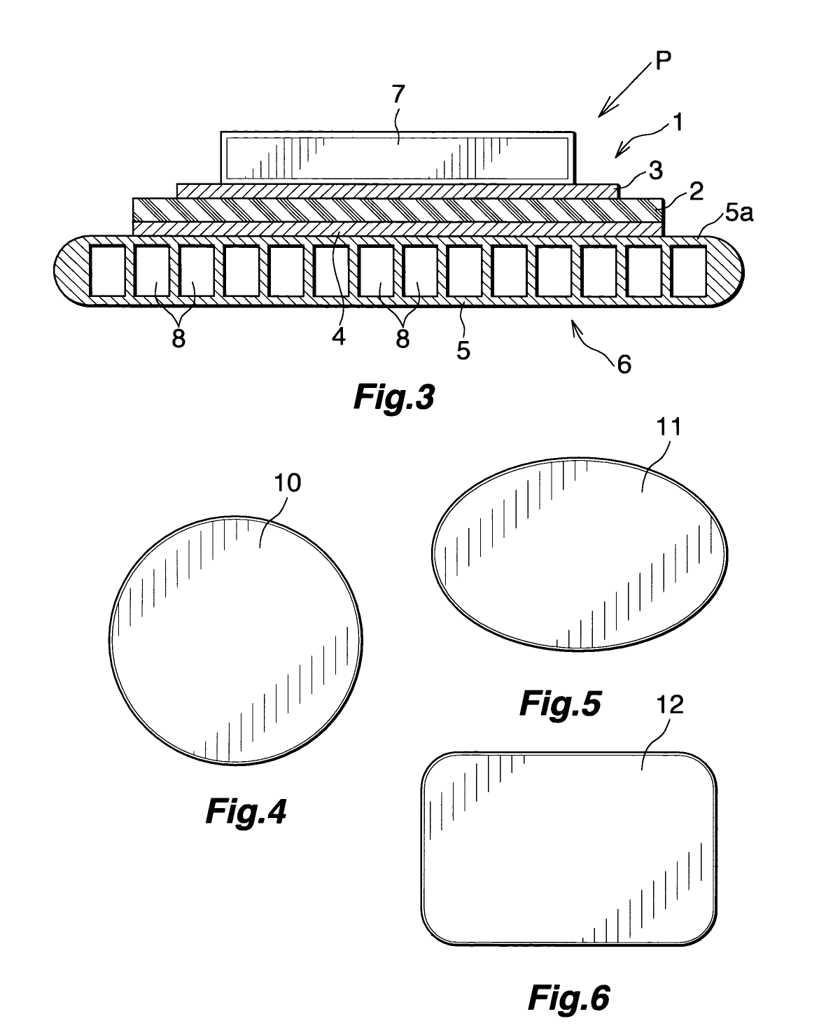

1. An insulating substrate comprising an electrically insulative layer; a wiring layer formed on one side of the electrically insulative layer and formed of a spark plasma sintered body of an electrically conductive material powder; and a stress relaxation layer formed on the other side of the electrically insulative layer and formed of a spark plasma sintered body of an alloy powder or a mixed powder to be formed into a metal composite.

2. An insulating substrate according to claim 1, wherein the electrically insulative layer is formed of a spark sintered body of a powder selected from the group consisting of an AlN powder, an Si₃N₄ powder, an Al₂O₃ powder, and a BeO powder.

3. An insulating substrate according to claim 1, wherein the wiring layer is formed of a spark sintered body of a powder selected from the group consisting of an Al powder, a Cu powder, an Ag powder, and an Au powder.

4. An insulating substrate according to claim 1, wherein the stress relaxation layer is formed of a spark plasma sintered body of a powder selected from the group consisting of an Al—Si alloy powder, a mixed powder of a Cu powder and an Mo powder, a mixed powder of a Cu powder and a W powder, a mixed powder of an Al powder and an SiC powder, and a mixed powder of an Si powder and an SiC powder.

5. An insulating substrate according to claim 1, wherein a thermal expansion coefficient of the stress relaxation layer falls between a thermal expansion coefficient of the electrically insulative layer and a thermal expansion coefficient of the wiring layer.

6. An insulating substrate according to claim 1, wherein at least the stress relaxation layer selected from the wiring layer and the stress relaxation layer has a circular shape.

7. An insulating substrate according to claim 1, wherein at least the stress relaxation layer selected from the wiring layer and the stress relaxation layer has an elliptic shape.

8. An insulating substrate according to claim 1, wherein at least the stress relaxation layer selected from the wiring layer and the stress relaxation layer has a polygonal shape having radiused corners.

9. A power module base comprising an insulating substrate according to claim 1 and a heat sink, to which the stress relaxation layer of the insulating substrate is welded or brazed.

10. A power module base comprising an insulating substrate according to claim 1 and a heat sink, to which the stress relaxation layer of the insulating substrate is bonded by means of a highly heat conductive adhesive.

11. A method of manufacturing an insulating substrate comprising forming a wiring layer on one side of an electrically insulative layer in the form of an insulating plate through spark plasma sintering of an electrically conductive material powder, and forming a stress relaxation layer on the other side of the electrically insulative layer through spark plasma sintering of an alloy powder or a mixed powder to be formed into a metal composite.

12. A method of manufacturing an insulating substrate according to claim 11, wherein the electrically insulative layer in the form of an insulating plate is formed through spark plasma sintering of a powder selected from the group consisting of an AlN powder, an Si₃N₄ powder, an Al₂O₃ powder, and a BeO powder.

13. A method of manufacturing an insulating substrate according to claim 11, wherein the electrically conductive material powder used to form the wiring layer is a powder selected from the group consisting of an Al powder, a Cu powder, an Ag powder, and an Au powder.

14. A method of manufacturing an insulating substrate according to claim 11, wherein the alloy powder which is used to form the stress relaxation layer is an Al—Si alloy, and the mixed powder to be formed into a metal composite which is used to form the stress relaxation layer is a mixed powder selected from the group consisting of a mixed powder of a Cu powder and an Mo powder, a mixed powder of a Cu powder and a W powder, a mixed powder of an Al powder and an SiC powder, and a mixed powder of an Si powder and an SiC powder.

15. A power module base comprising an insulating substrate according to claim 2 and a heat sink, to which the stress relaxation layer of the insulating substrate is welded or brazed.

16. A power module base comprising an insulating substrate according to claim 3 and a heat sink, to which the stress relaxation layer of the insulating substrate is welded or brazed.

17. A power module base comprising an insulating substrate according to claim 4 and a heat sink, to which the stress relaxation layer of the insulating substrate is welded or brazed.

18. A power module base comprising an insulating substrate according to claim 2 and a heat sink, to which the stress relaxation layer of the insulating substrate is bonded by means of a highly heat conductive adhesive.

19. A power module base comprising an insulating substrate according to claim 3 and a heat sink, to which the stress relaxation layer of the insulating substrate is bonded by means of a highly heat conductive adhesive.

20. A power module base comprising an insulating substrate according to claim 4 and a heat sink, to which the stress relaxation layer of the insulating substrate is bonded by means of a highly heat conductive adhesive.
